(19) United States
(12) Patent Application Publication
(10) Pub. No.: US 2006/0049473 A1
(43) Pub. Date: Mar. 9, 2006

(54) Spin polarization of charge carriers

(76) Inventors: Jean Joseph Heremans, Athens, OH (US); Hong Chen, Athens, OH (US)

Correspondence Address: CALFEE HALTER & GRISWOLD, LLP, 800 SUPERIOR AVENUE, SUITE 1400, CLEVELAND, OH, 44114, US

(21) Appl. No.: 11/206,647

(22) Filed: Aug. 18, 2005

Related U.S. Application Data
(60) Provisional application No. 60/602,416, filed on Aug. 18, 2004.

(51) Int. Cl. H01L 43/00; H01L 29/82

(52) U.S. Cl. 257/421; 257/422; 257/425

(57) ABSTRACT

Methods and devices for producing spin polarized charge carriers are provided. The devices utilize semiconductors exhibiting spin orbit coupling, at least one barrier and at least one aperture. The at least one aperture is positioned such that charge carriers having a first polarization after reflecting off of the barrier can pass through the first aperture.

### CROSS REFERENCE TO RELATED APPLICATIONS

This application claims priority to and any other benefit of U.S. Provisional Application No. 60/602,416, filed Aug. 18, 2004, which is incorporated by reference in its entirety herein.

### STATEMENT REGARDING FEDERALLY FUNDED RESEARCH

This invention was partially supported by a Federal Grant from the National Science Foundation (Grant Number DMR 0094055). The government has certain rights in this invention.

### FIELD OF THE INVENTION

The present invention relates to devices and methods of making devices that may be used to create spin-polarized charge carriers. More specifically, the present invention relates to devices and methods of making devices that may create and capture spin-polarized charge carriers.

### BACKGROUND OF THE INVENTION

Spin-polarized charge carriers are a factor in the realization of spin-based electronic device concepts. Additionally, spin-polarized charge carriers play a role in the realization of quantum computational schemes. Thus, there remains a need in the art for devices and methods for creating spin-polarized charge carriers.

### SUMMARY OF THE INVENTION

In accordance with an embodiment of the present invention, a device for spin polarization of charge carriers is provided. The device comprises a semiconductor, at least one barrier in the semiconductor, and at least one first aperture in the semiconductor. The semiconductor exhibits spin orbit coupling. A plurality of charge carriers may reflect off of the barrier, and one of the plurality of charge carriers may exhibit one of a first polarization and a second polarization after reflecting off of the barrier. The at least one first aperture is positioned such that the plurality of charge carriers having the first polarization may pass through the first aperture.

In accordance with another embodiment of the present invention, a method of spin polarizing a charge carrier is provided. The method includes forming a pattern in a semiconductor that exhibits spin orbit coupling. The pattern comprises at least one barrier and at least one aperture. The method further includes injecting at least one charge carrier toward the barrier such that the at least one charge carrier reflects off of the barrier, and the at least one charge carrier exhibits one of a first spin polarization and a second spin polarization after reflecting off of the barrier. The method also includes collecting the at least one charge carrier exhibiting the first spin polarization through the first aperture.

### BRIEF DESCRIPTION OF THE SEVERAL VIEWS OF THE DRAWINGS

The following detailed description of the preferred embodiments of the present invention can be best understood when read in conjunction with the following drawings, where like structure is indicated with like reference numerals and in which:

FIGS. 1A-1B are schematic illustrations of an exemplary spin polarization device in accordance with embodiments of the present invention;

FIGS. 2A-2B are schematic illustrations of another exemplary spin polarization device in accordance with embodiments of the present invention;

FIG. 3 is a schematic illustration of an exemplary spin transistor in accordance with embodiments of the present invention; and

FIG. 4 is a plot of four-contact resistance of triangular spin polarization devices S₁ and S₂ versus a perpendicular applied magnetic field B.

### DETAILED DESCRIPTION OF PREFERRED EMBODIMENTS

The present invention will now be described with occasional reference to the specific embodiments of the invention. This invention may, however, be embodied in different forms and should not be construed as limited to the embodiments set forth herein. Rather, these embodiments are provided so that this disclosure will be thorough and complete.

Unless otherwise defined, all technical and scientific terms used herein have the same meaning as commonly understood by one of ordinary skill in the art to which this invention belongs. The terminology used in the description of the invention herein is for describing particular embodiments only and is not intended to be limiting of the invention. As used in the description of the invention and the appended claims, the singular forms “a,” “an,” and “the” are intended to include the plural forms as well, unless the context clearly indicates otherwise. All publications, patent applications, patents, and other references mentioned herein are incorporated by reference in their entirety.

Unless otherwise indicated, all numbers expressing quantities of ingredients, properties such as molecular weight, reaction conditions, and so forth as used in the specification and claims are to be understood as being modified in all instances by the term “about.” Accordingly, unless otherwise indicated, the numerical properties set forth in the following specification and claims are approximations that may vary depending on the desired properties sought to be obtained in embodiments of the present invention. Notwithstanding that the numerical ranges and parameters setting forth the broad scope of the invention are approximations, the numerical values set forth in the specific examples are reported as precisely as possible. Any numerical values, however, inherently contain certain errors necessarily resulting from error found in their respective measurements.

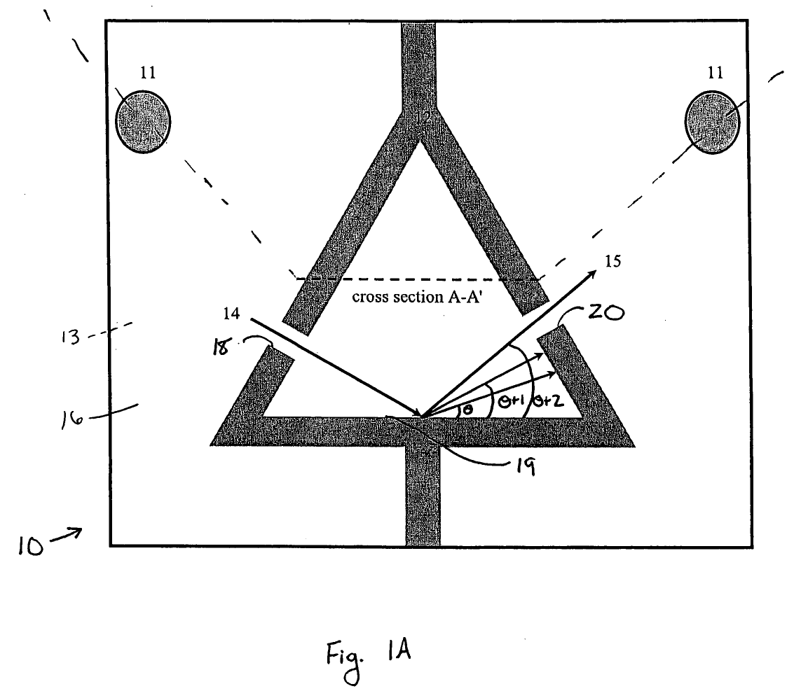

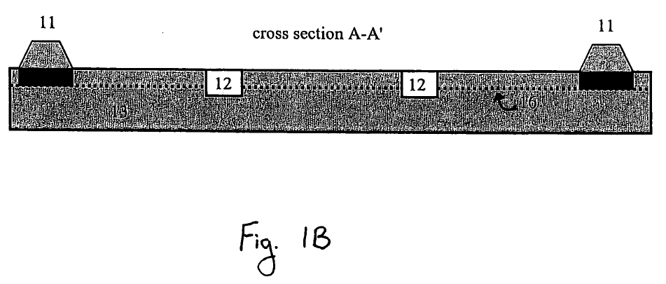

Referring to FIGS. 1A and 1B, a device 10 for creating spin-polarized carriers is illustrated. The device 10 comprises a semiconductor heterostructure 13 having a two-dimensional carrier system 16 contained therein. The heterostructure 13 has a pattern 12, and the pattern 12 may have at least a first opening 18. Additionally, the device 10 may have at least one electrical contact 11. The exemplary device shown in FIGS. 1A and 1B also has a barrier 19 and a second opening 20.

The heterostructure 13 comprises at least one material that exhibits spin orbit coupling. Additionally, the heterostructure 13 may comprise at least one material that exhibits spin orbit coupling and a long mean free path. For purposes of defining and describing the present invention, it will be understood that the term “mean free path” refers to the average distance that a charge carrier travels before an interaction occurs. Suitable heterostructures 13 include, but are not limited to, heterostructures having GaAs, InAs, InGaAs, GaSb, AlGaSb, InSb, and/or InAlSb layers. Any suitable n-type or p-type heterostructure can be used. For example, the heterostructure 13 may comprise an n-type InSb/InAlSb heterostructure. In another example, the heterostructure 13 can comprise an InAs/GaSb heterostructure. In yet another example, the heterostructure 13 can comprise an InAs/AlGaSb heterostructure. It will be understood that two-dimensional carrier systems 16 may exist buried in the heterostructure 13 where electrons or holes are trapped at the interface between at least two of the layers of the heterostructure 13.

As illustrated in FIG. 1A, the pattern 12 may be a triangularly shaped pattern. The pattern 12 is disposed such that the motion of the charge carrier 14 through the pattern 12 comprises ballistic motion. For purposes of defining and describing the present invention, the term “ballistic motion” shall be understood as referring to motion wherein the preponderant scattering events involve the boundaries of the device 10. The pattern 12 may have any suitable dimensions. In one embodiment, the distance that the charge carrier 14 travels through the pattern 12 is no smaller than the wavelength of the charge carrier 14. In another embodiment, the distance that the charge carrier 14 travels through the pattern 12 is no greater than the mean free path of the charge carrier 14. For example, the distance may be about 20 nm to about 100 μm if the charge carrier is an electron. A charge carrier 14 may enter the first opening 18 and reflect off of the bottom barrier wall 19 in the direction of the second opening 20. The charge carrier 14 may have any suitable angle of incidence to the bottom barrier wall 19, depending on the material, to give desired angles of reflection. The charge carrier 14 travels ballistically from the first opening 18 to the barrier 19 and from the barrier 19 to the second opening 20. It will be understood that the left and right portions of the pattern 12 having the first and second openings 18, 20 are also scattering barriers. The charge carrier 14 may be injected by the electrical contacts 11 from a suitably doped semiconductive layer or in any other suitable manner.

Both the energy and the momentum parallel to the barrier 19 are conserved during the scattering of the charge carrier 14 off of the barrier 19. However, in the presence of spin orbit coupling, scattering off of the barrier 19 leads to spin-flip events, and the charge carrier 14 may exhibit a different reflection angle for different spin polarizations. For example, the charge carrier 14 may reflect off the barrier 19 at an angle of θ, θ+1, or θ+2. It will be understood that the angles illustrated in FIG. 1A are intended to be exemplary only. The second opening 20 may be disposed such that only charge carriers 15 having a desired spin may pass through the second opening 20. Thus, only the charge carriers 15 that reflect at the desired angle may pass through the opening in the pattern 12. Therefore, charge carriers 15 having a first polarization can pass through the opening 20 at the exclusion of charge carriers having another or a second polarization. Therefore, the charge carriers 15 having a desired spin can be filtered from other charge carriers, and the charge carriers 15 having the desired spin may be collected to form a population with a known spin polarization.

Alternatively, a magnetic field (not shown) oriented perpendicular to the pattern 12 may be applied in order to select which trajectory may exit the second opening 20. In a further embodiment, an additional opening (not shown) may be provided such that charge carriers 15 having a different angle of reflection may pass through the additional opening.

The pattern 12 may be formed in any suitable manner. For example, the pattern 12 may be etched into the heterostructure 13 using any suitable etching method. For example, the pattern 12 may be wet etched or dry etched after electron beam lithography. The pattern 12 may also be formed by depositing a pattern on the heterostructure 13 and gating the pattern 12. For example, the pattern 12 could be gated with a voltage greater than zero for positive charge carriers and a voltage less than zero for negative charge carriers. In another example, the pattern 12 can be formed by implanting a suitable dopant into the heterostructure to provide disordered areas. The pattern 12 can be formed by ion beam milling to remove portions of the heterostructure and form the pattern 12.

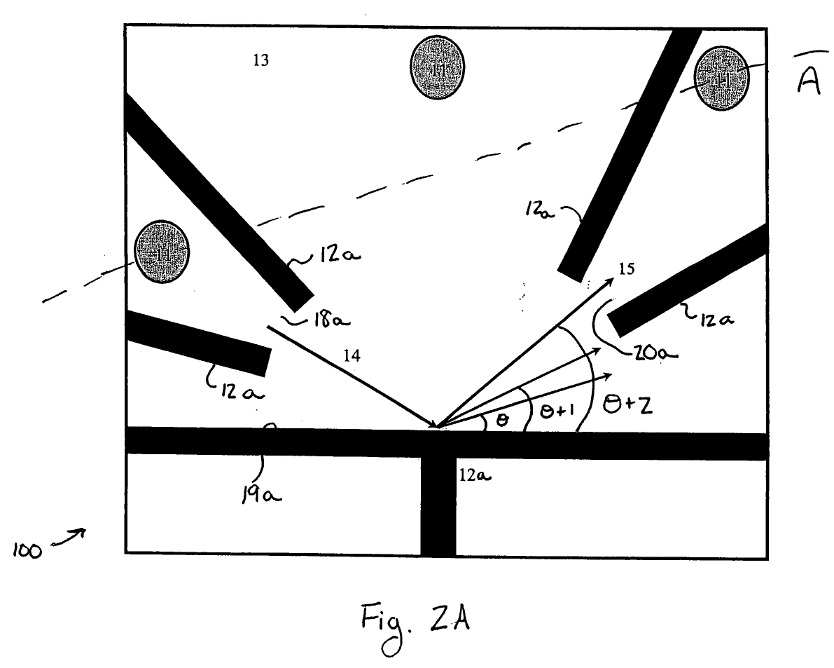

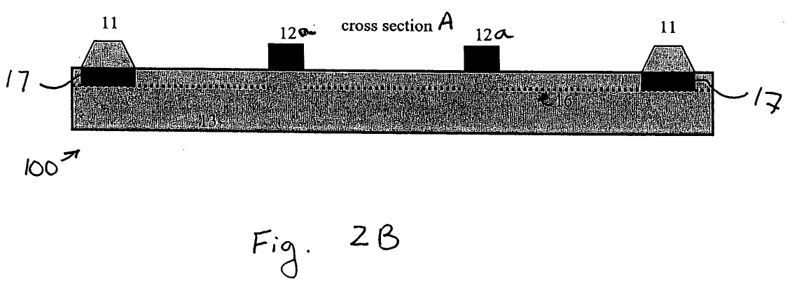

Referring to FIGS. 2A and 2B, a device 100 for creating spin-polarized carriers is illustrated. The device 100 comprises a semiconductor heterostructure 13 having a two-dimensional carrier system 16 contained therein. The heterostructure 13 has patterns 12a, and the pattern 12a may have at least a first open area 18a and a second open area 20a. Additionally, the device 100 may have at least one electrical contact 11. The heterostructure 13 may be any suitable heterostructure, and the heterostructure 13 may be as described in conjunction with FIGS. 1A and 1B. It will be understood that two-dimensional carrier systems 16 may exist buried in the heterostructure 13 where electrons or holes are trapped at the interface between at least two of the layers of the heterostructure 13.

As illustrated in FIG. 2A, the patterns 12a may be disposed to form a first opening 18a and a second opening 20a disposed near a barrier wall 19a. The patterns 12a are disposed such that the motion of the charge carrier 14 through the patterns 12a comprises ballistic motion. The patterns 12a may have any suitable dimensions. In one embodiment, the distance that the charge carrier 14 travels through the patterns 12a is no smaller than the wavelength of the charge carrier 14. In another embodiment, the distance that the charge carrier 14 travels through the patterns 12a is no greater than the mean free path of the charge carrier 14. For example, the distance may be about 20 nm to about 100 μm if the charge carrier is an electron. A charge carrier 14 may enter the first opening 18a and reflect off of the bottom barrier wall 19a in the direction of the second opening 20a. The charge carrier 14 may have any suitable angle of incidence to the bottom barrier wall 19a, depending on the material, to give desired angles of reflection. The charge carrier 14 travels ballistically from the first opening 18a to the barrier 19a and from the barrier 19a to the second opening 20a. The charge carrier 14 may be injected by the electrical contacts 11 from a suitably doped semiconductive layer 17 or in any other suitable manner.

Both the energy and the momentum parallel to the barrier 19a are conserved during the scattering of the charge carrier 14 off of the barrier 19a. However, in the presence of spin orbit coupling, scattering off of the barrier 19a leads to spin-flip events, and the charge carrier 14 may exhibit a different reflection angle for different spin polarizations. For example, the charge carrier 14 may reflect off the barrier 19a at an angle of θ, θ+1, or θ+2. It will be understood that the angles illustrated in FIG. 2A are intended to be exemplary only. The second opening 20a may be disposed such that only charge carriers 15 having a desired spin, such as an angle of θ+2, may pass through the second opening 20a. Thus, only the charge carriers 15 that reflect at the desired angle may pass through the second opening 20a in the patterns 12a. Alternatively, a magnetic field (not shown) oriented perpendicular to the patterns 12a may be applied in order to select which trajectory may exit the second opening 20a. In another embodiment, an additional opening or openings (not shown) may be provided such that charge carriers 15 having a different angles of reflection may pass through the additional openings.

The patterns 12a may be formed in any suitable manner. For example, the patterns 12a may be etched into the heterostructure 13 using any suitable etching method. For example, the patterns 12a may be wet etched or dry etched after electron beam lithography. The pattern 12a may also be formed by depositing a pattern on the heterostructure 13 and gating the pattern. For example, the patterns 12a could be gated with a voltage greater than zero for positive charge carriers and a voltage less than zero for negative charge carriers. In another example, the pattern 12a can be formed by implanting a suitable dopant into the heterostructure to provide disordered areas. The pattern 12a can be formed by ion beam milling to remove portions of the heterostructure and form the pattern 12a.

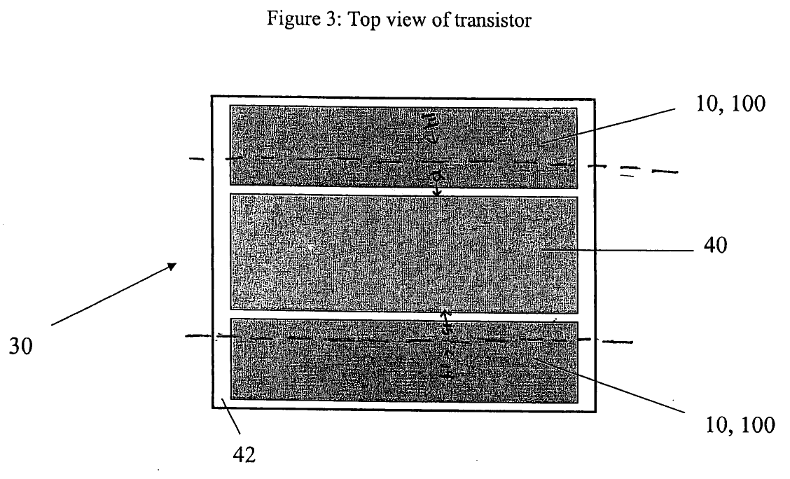

Referring now to FIG. 3, the devices 10, 100 illustrated in FIGS. 1A-2B may be utilized as the source or drain 10, 100 of a spin transistor 30. For example, the device 10, 100 may be disposed such that charge carriers 14 are spin-polarized as discussed herein to desired spin-polarized charge carriers 15. The spin transistor 30 may have a source and drain 10,100 and a gate 40 disposed on any suitable heterostructure 42. The spin transistor 30 may have any suitable structure. In this manner, a transistor that utilizes the spin, rather than the charge, of a charge carrier may be formed. Such a spin transistor 30 may be useful in a variety of computer applications, since it can lead to chips that consume less power, are smaller, and yet are more powerful for some tasks than presently existing chips.

### EXAMPLE

Devices having patterns comprising equilateral triangles similar to FIG. 1A were formed. The equilateral triangles had inside dimensions of 3.0 μm and apertures, of conducting widths of about 0.2 μm, on two sides. The left side of the triangle formed a scattering barrier. Several triangles were measured in parallel.

The triangles were wet etched into n-type InSb/InAlSb heterostructures after electron beam lithography. The gentle wet-etching procedure may provide highly reflecting barriers in III-V heterostructures. The heterostructures were grown by molecular beam epitaxy on GaAs substrates, and consisted of a 20 nm wide InSb well, where the two-dimensional electron system (2DES) resides, flanked by In_{0.91}A_{0.09}Sb barrier layers.

Carriers enter the geometry from the left side, travel ballistically to the bottom barrier, reflect off the latter, and exit through the right side aperture similar to FIG. 1A. The total distance, including the reflection, between the apertures, amounts to 2.6 μm. Electrons are provided by Si δ-doped layers on both sides of the well, separated from the 2DES in the well by 30 nm spacers. A third Si doped layer lies close to the heterostructure surface.

All measurements were performed at 0.5 K, and at this temperature, a density N_{S}=2.6×10¹¹ cm⁻² and a mobility of 150,000 cm²/Vs provide a mean free path of ˜1.3 μm. Although shorter than the distance between the two apertures in the equilateral triangle, this mean free path is sufficiently long to ensure observation of a signal due to a ballistic trajectory. Indeed, the cutoff of the signal at the mean free path is not abrupt, but rather is characterized by a gradual decay of the signal amplitude.

The InSb well material features a narrow energy gap, a small effective mass, and also a strong spin orbit interaction (SOI). Two SOI mechanisms can lead to the spin-dependent reflection effect: the Bychkov-Rashba mechanism, originating in the inversion asymmetry of the 2DES confining potential, and the Dresselhaus mechanism, from the bulk inversion asymmetry. Experimental values for the SOI parameters in InSb-based heterostructures have only recently been accessed by optical measurements, and the preliminary data confirms SOIs larger than in most other III-V materials.

In the measurements, a current was drawn between the two apertures of the equilateral triangle, and the resulting voltage drop was measured as a function of a magnetic field applied perpendicular to the plane of the 2DES. In the semi-classical limit, the magnetic field B serves to slightly deflect the ballistic carriers from linear trajectories, and thus to sweep the trajectories over the exit aperture. The interaction with the barrier gives rise to three reflection angles, and the exit (lower) aperture is sufficiently wide to accommodate the three resulting exiting beams. For a narrow range of B, all three beams can be aimed to pass through the aperture. Varying B in either direction causes the beams to be sequentially cut off, either by one side of the aperture or by the other. Each cutoff results in a stepwise rise in the potential or resistance measured over the structure.

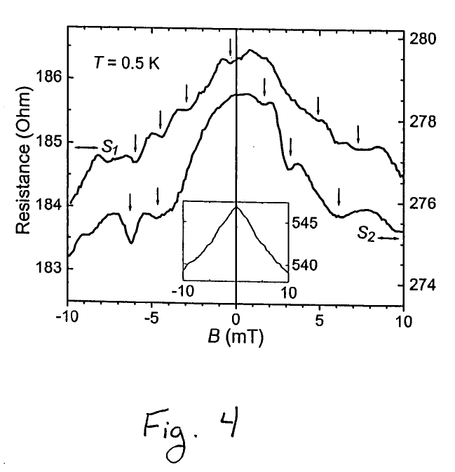

FIG. 4 shows experimental data for two separate samples (S₁ and S₂), plotted as the four-contact resistance measured over the triangular structures, versus applied B. For sample S₁, 6 minima appear at low B, superimposed on a negative magnetoresistance weak-localization background. The 6 minima are interpreted to result from the stepwise increase in resistance as B is varied, added to the negative magnetoresistance background. We also note here that the wet-etching process results in uncertainty in the structure's dimensions, and that therefore a non-zero B may have to be applied to center the three beams on the exit aperture. Hence, the 6 minima need not be centered around B=0.

Sample S₂ underwent a deeper wet-etch, resulting in narrower apertures, as betrayed by the higher resistance values. Hence, the range of B where three beams fit into the exit aperture of S₂ is reduced as compared to S₁. Two steps in resistance occur in such a narrow range of B that they are observed as one, resulting in 5 observable minima. Assuming that the Bychkov-Rashba mechanism leads to the observed minima, the data can be used to estimate the magnitude of the spin splitting. SOI can be evaluated by the spin-splitting Δ_{SO} at the Fermi level E_{F}, given by Δ_{SO}=2α_{SO}k_{F}, where k_{F} denotes the Fermi wave vector and α_{SO} depends on material and heterostructure parameters. Estimating α_{SO} from the experiments, we have calculated the values of B where cutoffs occur, using the equations derived below for the angular deviations from specular reflection, Δθ_{+→-} and Δθ_{-→+}.

The following parameters are consistent with our experimental observations: α_{SO}≈1×10⁻⁶ meV cm and Δ_{SO}≈2.5 meV, at N_{S}=2.6×10¹¹ cm⁻² and E_{F}=35 meV (the effective mass mₑ=0.014 m₀). This value for Δ_{SO} approaches that obtained from the optical measurements on similar InSb/InAlSb heterostructures.

Returning to the negative magnetoresistance background, we have consistently observed only a weak-localization peak at B≈0 in mesoscopic geometries fabricated in the InSb/InAlSb heterostructure, in contrast to the antilocalization signature observed in GaAs or InAs based 2DESs. Another example of a weak-localization peak in a mesoscopic geometry is shown in the inset in FIG. 4, namely the resistance vs. applied perpendicular B, measured over an anti-dot lattice fabricated on the same heterostructure [12]. The absence of antilocalization is not surprising in InSb. Antilocalization requires the Dyakonov-Perel' spin scattering mechanism to dominate, leading to a randomization of the spin precession process due to a weak SOI. Yet, due to large spin splitting in InSb, the impurity broadening of the electron energy is less than the spin-splitting, invalidating the conditions for Dyakonov-Perel' scattering and antilocalization (h/τ≈0.5 meV<<Δ_{SO}≈2.5 meV, where τ is the scattering time deduced from the mobility mean free path).

The present invention should not be considered limited to the specific examples described above, but rather should be understood to cover all aspects of the invention. Various modifications, equivalent processes, as well as numerous structures and devices to which the present invention may be applicable will be readily apparent to those of skill in the art.

It will be obvious to those skilled in the art that various changes may be made without departing from the scope of the invention, which is not to be considered limited to what is described in the specification.

1. A device for spin polarization of charge carriers, comprising:
a semiconductor, wherein said semiconductor exhibits spin orbit coupling;
at least one barrier in said semiconductor, wherein a plurality of charge carriers may reflect off of said barrier, and wherein each one of said plurality of charge carriers may exhibit one of a first polarization and a second polarization after reflecting off of said barrier; and
at least one aperture in said semiconductor, wherein said at least one aperture is positioned such that said plurality of charge carriers reflecting off of said barrier having said first polarization may pass through said aperture.

2. The device as claimed in claim 1 wherein said charge carriers having said second polarization may do pass through said aperture.

3. The device as claimed in claim 1 wherein said semiconductor comprises a heterostructure.

4. The device as claimed in claim 3 wherein said heterostructure comprises at least a GaAs, InAs, InGaAs, GaSb, AlGaSb, InSb, or InAlSb layer.

5. The device as claimed in claim 1 wherein said charge carrier comprises an electron.

6. The device as claimed in claim 1 wherein said charge carrier comprises a hole.

7. The device as claimed in claim 1 wherein said barrier and said aperture comprise a pattern.

8. The device as claimed in claim 7 wherein said pattern comprises a pattern etched into said semiconductor.

9. The device as claimed in claim 7 wherein said pattern comprises a pattern deposited on said semiconductor and gated with at least one voltage.

10. The device as claimed in claim 7 wherein the distance that said charge carrier travels through said pattern is no smaller than the wavelength of said charge carrier.

11. The device as claimed in claim 7 wherein the distance that said charge carrier travels through said pattern is no greater than the mean free path of said charge carrier.

12. The device as claimed in claim 7 wherein said pattern comprises a triangularly shaped pattern, and wherein said pattern has a second aperture.

13. The device as claimed in claim 12 wherein said charge carrier enters said pattern through said second aperture reflects off of said barrier and moves toward said aperture.

14. The device as claimed in claim 7 wherein said pattern further comprises a second aperture disposed such that said charge carriers enter said pattern via said second aperture.

15. The device as claimed in claim 7 wherein said pattern further comprises a first blocking barrier having a first aperture, a reflective barrier, and a second blocking barrier having a second aperture, and wherein said first blocking barrier, said reflective barrier, and said second blocking barrier are arranged into a generally triangular arrangement.

16. The device as claimed in claim 1 wherein said semiconductor has at least one additional aperture, wherein said at least one additional aperture is positioned such that said plurality of charge carriers having said second polarization pass through said additional aperture.

17. The device as claimed in claim 1 wherein said device comprises the source or drain of a transistor.

18. A method of spin polarizing a charge carrier comprising:
forming a pattern in a semiconductor that exhibits spin orbit coupling, wherein said pattern comprises at least one barrier and at least one aperture;
injecting at least one charge carrier toward said barrier such that said at least one charge carrier reflects off of said barrier, wherein said at least one charge carrier exhibits one of a first spin polarization and a second spin polarization after reflecting off of said barrier; and
collecting the charge carrier exhibiting said first spin polarization through said at least one aperture.

19. The method as claimed in claim 18 wherein the step of injecting at least one charge carrier comprises injecting a plurality of charge carriers toward said barrier such that the plurality of charge carriers reflect off of said barrier such that selected ones of the plurality of charge carriers have a first spin polarization and selected ones of the plurality of charge carriers have second polarization after reflecting off of said barrier.

20. The method as claimed in claim 18 wherein the step of forming a pattern comprises forming a triangularly shaped pattern having at least one barrier, a first aperture, and a second aperture.

21. The method as claimed in claim 18 wherein said step of forming a pattern comprises forming a pattern having a first blocking barrier having a first aperture, a reflective barrier, and a second blocking barrier having a second aperture, and wherein said first blocking barrier, said reflective barrier, and said second blocking barrier are arranged into a generally triangular arrangement.

22. The method as claimed in claim 18 wherein:
said step of forming a pattern comprises forming a pattern having a barrier, a first aperture, and a second aperture;
said step of injecting at least one charge carrier comprises injecting said at least one charge carrier through said first aperture; and
said step of collecting comprises collecting said charge carrier having said first spin polarization through said second aperture.
